(19) United States
(12) Patent Application Publication
(10) Pub. No.: US 2010/0101829 A1
(43) Pub. Date: Apr. 29, 2010

(54) MAGNETIC NANOWIRES FOR TCO REPLACEMENT

(76) Inventors: Steven VERHAVERBEKE, San Francisco, CA (US); Omkaram Nalamasu, San Jose, CA (US); Nety M. Krishna, Sunnyvale, CA (US)

Correspondence Address: APPLIED MATERIALS;C/O PILLSBURY WINTHROP SHAW PITTMAN LLP, P .O . BOX 10500, MCLEAN, VA, 22120, US

(21) Appl. No.: 12/258,263

(22) Filed: Oct. 24, 2008

(51) Int. Cl. H01B 5/00; H05K 3/10

(52) U.S. Cl. 174/126.2; 29/846

(57) ABSTRACT

This invention provides an optically transparent conductive layer with a desirable combination of low electrical sheet resistance and good optical transparency. The conductive layer comprises a multiplicity of magnetic nanowires in a plane, the nanowires being aligned roughly (1) parallel to each other and (2) with the long axes of the nanowires in the plane of the layer, the nanowires further being configured to provide a plurality of continuous conductive pathways, and wherein the density of the multiplicity of magnetic nanowires allows for substantial optical transparency of the conductive layer. Furthermore, the conductive layer can include an optically transparent continuous conductive film, wherein the multiplicity of magnetic nanowires are electrically connected to the continuous conductive film. A method of forming the conductive layer on a substrate includes: depositing a multiplicity of magnetic conductive nanowires on the substrate and applying a magnetic field to form the nanowires into a plurality of conductive pathways parallel to the surface of the substrate.

### FIELD OF THE INVENTION

The present invention relates generally to transparent conductive films and more specifically to a transparent conductive film comprising magnetic nanowires.

### BACKGROUND OF THE INVENTION

Optically transparent conductor layers are used in a variety of applications where a transparent conductor is either required or provides an advantage. Applications using transparent conductors include: liquid crystal displays, plasma displays, organic light emitting diodes, solar cells, etc. The transparent conducting oxides (TCOs), such as indium tin oxide and zinc oxide, are the most commonly used transparent conductor materials. However, TCO films represent a compromise between electrical conductivity and optical transparency—as carrier concentrations are increased to improve electrical conductivity, the optical transparency is reduced, and vice-à-versa. Furthermore, as the thickness of the TCO film is increased to improve electrical sheet resistance, the optical transparency is reduced. There is a need for optically transparent conductors with a more favorable compromise between electrical conductivity and optical transparency.

FIG. 1 shows a prior art solar cell device 100. Solar cell device 100 comprises a glass substrate 110, transparent conducting electrode (TCO) 120, active layer 130, and bottom electrode 140. Electron-hole pairs are generated in the active layer 130 by photons from light source 105 which travel through the glass substrate 110 and TCO 120 to reach the active layer 130. Individual cells, which generate a small voltage (typically 0.5-0.6 volts), are combined in series as shown in FIG. 1. The cells have a total width comprising the width of the active area of the cell, W_{A}, where electron-hole pairs contribute to the power generated, and the width of the dead area of the cell, W_{D}, where electron-hole pairs do not contribute. Current 150 flows through the device 100 as indicated. It is clear from the path followed by the current 150 that the sheet resistances of the TCO 120 and bottom electrode 140 are important in determining the resistive losses in the solar cell device 100. Further, these resistive losses will determine the maximum ratio of active cell area, indicated by W_{A}, to dead cell area, indicated by W_{D}. (The lower the resistive losses, the larger the ratio can be and the more efficient the device can be. See, for example, Brecl et al., Proc. 21^{st} European Photovoltaic Solar Energy Conference, 4-8 Sep. 2006, Dresden, Germany, pages 1662-1665.) Furthermore, it is clear that the efficiency of the solar cell device will be determined in part by the light transmission properties of the TCO 120. The sheet resistance of the TCO 120 is less for thicker films. Conversely, light transmission through the TCO 120 is greater for thinner films. Consequently, there is a compromise thickness for the TCO that will provide the best solar cell device performance. Again, there is a need for optically transparent conductors with a more favorable compromise between electrical conductivity and optical transparency.

Attempts to find a more favorable combination of optical transparency and electrical conductivity in a thin film optically transparent conductor have resulted in investigation of materials comprising two-dimensional networks of carbon nanotubes and silver nanowires. An example of the latter is shown in FIG. 2, which illustrates a thin film 210 comprising a random two-dimensional array of silver nanowires 220. For ease of illustration, FIG. 2 is not drawn to scale—it is intended only to illustrate the general nature of the arrangement of nanowires. Thin film 210 relies on the interconnection of individual nanowires 220 for electrical conductivity. The optical transparency comes from the low density of metal in the thin film 210. As can be seen in FIG. 2, the current pathways through the thin film 210 will be very convoluted and do not make efficient use of the silver nanowires 220. Furthermore, since the nanowires 220 are not being used efficiently to provide electrical conduction in the thin film 210, the film 210 will have a less than optimum optical transparency. Clearly, the combination of electrical conductivity and optical transparency that is available from thin films comprising nanowires has yet to be fully optimized.

### SUMMARY OF THE INVENTION

This invention provides an optically transparent conductive layer with a desirable combination of low electrical sheet resistance and good optical transparency. The transparent conductive layer is comprised of magnetic nanowires which are (1) at a low enough density to provide good optical transparency, and (2) arranged to optimize electrical conductivity. The concepts and methods of this invention allow for integration of the transparent conductive layer into devices such as solar cells, displays and light emitting diodes.

According to aspects of this invention, a conductive layer comprises a multiplicity of magnetic nanowires in a plane, the nanowires being aligned roughly (1) parallel to each other and (2) with the long axes of the nanowires in the plane of the layer, the nanowires further being configured to provide a plurality of continuous conductive pathways, and wherein the density of the multiplicity of magnetic nanowires allows for substantial optical transparency of the conductive layer. Furthermore, the conductive layer can include an optically transparent continuous conductive film, wherein the multiplicity of magnetic nanowires are electrically connected to the continuous conductive film; the continuous conductive film can be either coating the multiplicity of magnetic nanowires or the multiplicity of magnetic nanowires can be on the surface of the continuous conductive film.

According to further aspects of this invention, a method of forming a conductive layer on a substrate is provided, where the conductive layer is substantially optically transparent. The method comprises: depositing a multiplicity of magnetic conductive nanowires on the substrate; and applying a magnetic field to form the nanowires into a plurality of conductive pathways parallel to the surface of the substrate. The depositing step can include spraying a liquid suspension of the nanowires onto the surface of the substrate. After the depositing step, the nanowires can be coated with a conductive metal, for example by an electroless plating process.

### BRIEF DESCRIPTION OF THE DRAWINGS

These and other aspects and features of the present invention will become apparent to those ordinarily skilled in the art upon review of the following description of specific embodiments of the invention in conjunction with the accompanying figures, wherein:

FIG. 1 is a perspective view of a prior art solar cell;

FIG. 2 is a top view of a prior art conductive film comprising nanowires;

FIG. 3 is a top view of a conductive coating comprising magnetic nanowires, according to the invention;

FIG. 4 is a view of a vertically oriented substrate coated with magnetic nanowires prior to applying an external magnetic field, according to the method of the invention;

FIG. 5 is a view of the substrate of FIG. 4 after applying an external magnetic field, according to the invention;

FIG. 6 is a perspective view of a composite magnetic nanowire, according to the invention; and

FIG. 7 is a perspective view of a substrate with a transparent conductive layer comprising a conductive film and a layer of oriented magnetic nanowires, according to the invention.

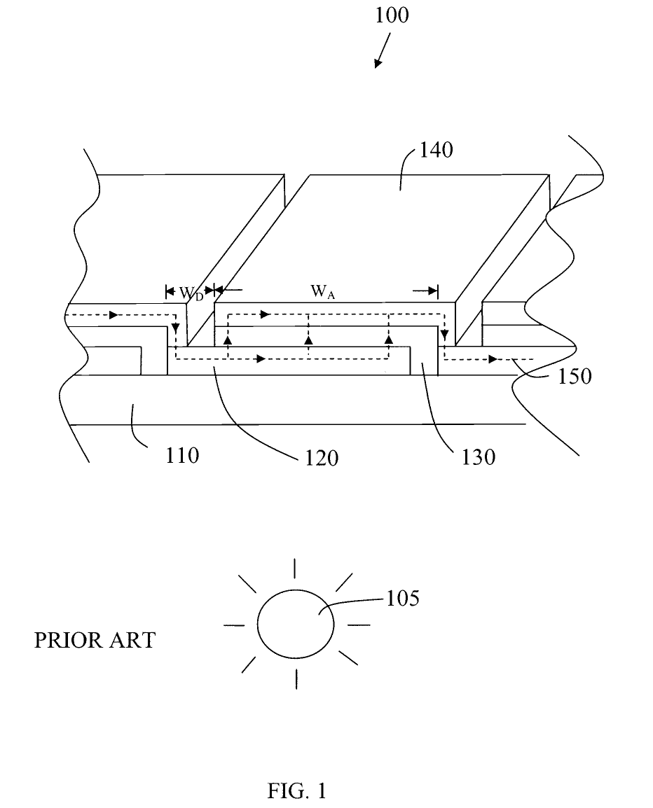

### DETAILED DESCRIPTION OF THE PREFERRED EMBODIMENTS

The present invention will now be described in detail with reference to the drawings, which are provided as illustrative examples of the invention so as to enable those skilled in the art to practice the invention. Notably, the figures and examples below are not meant to limit the scope of the present invention to a single embodiment, but other embodiments are possible by way of interchange of some or all of the described or illustrated elements. Moreover, where certain elements of the present invention can be partially or fully implemented using known components, only those portions of such known components that are necessary for an understanding of the present invention will be described, and detailed descriptions of other portions of such known components will be omitted so as not to obscure the invention. In the present specification, an embodiment showing a singular component should not be considered limiting; rather, the invention is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration.

In general, the present invention contemplates a conductive layer comprising magnetic nanowires with an optimal combination of both electrical conductivity and optical transparency. The magnetic nanowires are aligned in a magnetic field to form continuous conductive pathways in the plane of the conductive layer. The magnetic nanowires can be fabricated by electroless deposition in a template. For example, nickel metal can be deposited in the pores of porous anodized alumina. See Srivastava et al., Metallurgical and Materials Transactions A, 38A, 717 (2007). The magnetic nanowires are in the general range of 5 to 300 nm in diameter, preferably 10-100 nm in diameter, and most preferably 40 nm in diameter. The magnetic nanowires can have an aspect ratio—length to diameter—in the range of 5:1 to 100:1, and preferably 10:1. The length to diameter ratio is primarily limited by the fabrication method of the nanowires. If a template is used to fabricate the nanowires, then the template is limiting the length to diameter ratio. The nanowires comprise magnetic material, such as nickel metal, as discussed in more detail below.

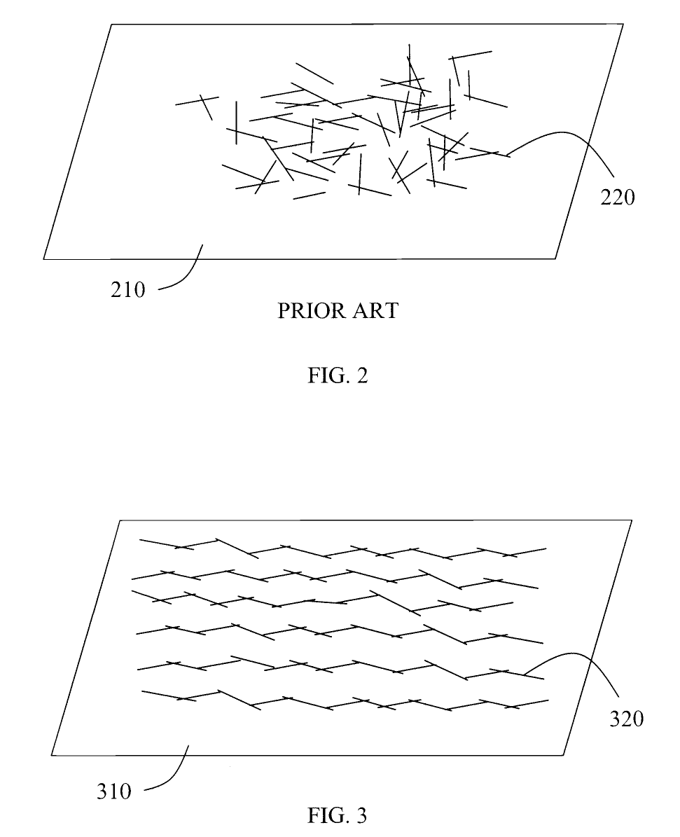

FIG. 3 shows a two-dimensional network of metallic nanowires according to the invention. For ease of illustration, FIG. 3 is not drawn to scale—it is intended only to illustrate the general nature of the arrangement of nanowires. The network of metallic nanowires in FIG. 3 provides a more favorable combination of optical transparency and electrical conductivity in a thin film optically transparent conductor than is available in the prior art shown in FIG. 2. FIG. 3 illustrates a thin film 310 comprising an ordered two-dimensional array of metallic nanowires 320. The thin film 310 can consist of the metallic nanowires 320 alone, distributed on the surface of a substrate. However, the thin film 310 can also comprise other materials, such as a continuous substantially optically transparent conductive film, as described below. The nanowires 320 are aligned roughly: (1) parallel to each other; and (2) with their long axes in the plane of the thin film 310. Thin film 310 relies on the interconnection of individual nanowires 320 for electrical conductivity—the nanowires 320 are configured to provide a plurality of continuous conductive pathways. (Six such pathways are illustrated in FIG. 3). The optical transparency comes from the low density of metal in the thin film 310. More specifically, for solar cell applications, substantial optical transparency is required for wavelengths below approximately 510 nm. (Photons with wavelengths below approximately 510 nm can produce electron-hole pairs in the active layer of a typical solar cell.) As can be seen in FIG. 3, the current pathways through the thin film 310 make optimum use of the nanowires 320. The combination of electrical conductivity and optical transparency provided by the present invention provides an advantage for applications such as solar cells.

Referring again to FIG. 3, a desirable spacing between adjacent continuous conductive pathways is in the range of 50 nm to 1 μm. This range provides a desirable combination of electrical conductivity and optical transparency for a thin film optically transparent conductor comprising nanowires.

The nanowires 320 in FIG. 3 are magnetic, allowing for their alignment using a magnetic field. The nanowires 320 comprise magnetic material, such as magnetic metals, magnetic alloys and magnetic compounds. In preferred embodiments the nanowires 320 comprise transition metals such as nickel, cobalt and iron.

Nanowires 320 can comprise a single magnetic metal or a combination of metals chosen for their magnetic and electrical conductive properties. FIG. 6 shows a compound nanowire 600. The nanowire 600 has a core 620 of a first metal and a coating 610 of a second metal. The core 620 can be a magnetic metal and the coating 610 can be a metal chosen for its high electrical conductivity. For example, the coating 610 can comprise a metal such as copper, silver, gold, palladium or platinum, or a suitable alloy. Alternatively, the coating 610 can be a magnetic metal and the core 620 can be a metal chosen for its high electrical conductivity.

A method according to the present invention for forming a conductive layer such as the thin film 310 shown in FIG. 3 includes the following steps. First, a substrate is provided. In the case of a solar device, the substrate can be a glass substrate. Second, magnetic, electrically conductive nanowires are deposited on the surface of the substrate. The deposition step can conveniently comprise spraying a liquid suspension of nanowires onto the surface of the substrate. Third, a magnetic field, with field lines parallel to the surface of the substrate, is applied, preferably while the substrate is still wet. The magnetic field forms the nanowires into a plurality of conductive pathways parallel to the magnetic field lines. The alignment of the nanowires to the magnetic field lines can be assisted by orienting the substrate such that the substrate surface is in a vertical plane. Furthermore, after the deposition step the nanowires can be coated with a conductive metal such as gold or silver, using techniques such as electroless plating. For example, nickel or cobalt nanowires can be immersion coated with silver or gold by a spray process such as electroless nickel immersion gold (ENIG), currently used to make solder bump pads with a thin layer of gold on a nickel pad. This immersion coating process can assist in fixing the nanowires in place in their aligned configuration.

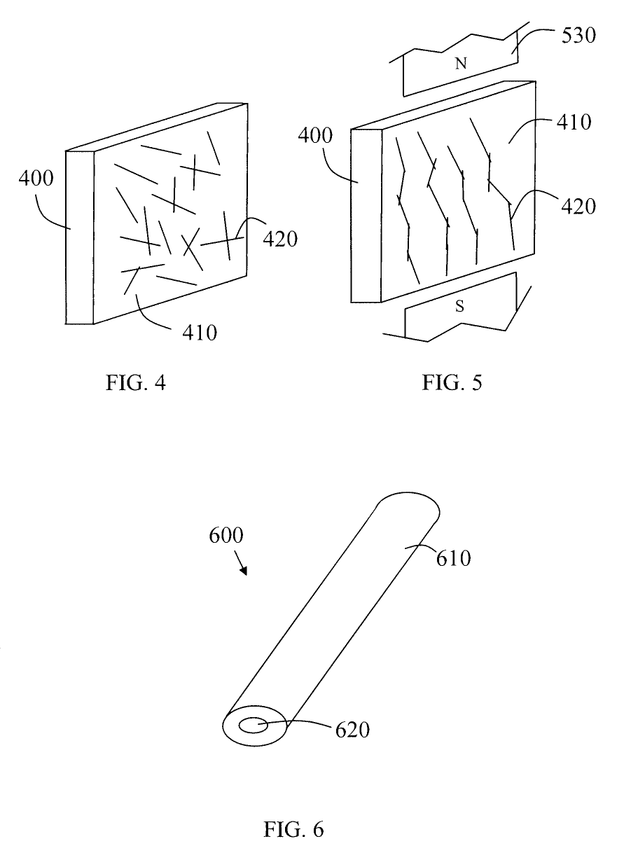

FIGS. 4 & 5 illustrate the effect of applying a magnetic field to magnetic nanowires 420 deposited on the surface 410 of a substrate 400. For ease of illustration, FIGS. 4 & 5 are not drawn to scale—it is intended only to illustrate the general nature of the arrangement of nanowires. In FIG. 4, the nanowires 420 are shown in their as-deposited arrangement on the surface 410—this arrangement is a substantially random two-dimensional arrangement. In preferred embodiments of the method, the substrate 400 is oriented with the surface 410 in a vertical plane. A magnetic field can be applied by magnet(s) 530, as illustrated in FIG. 5. The magnetic field can also be applied using a coil. There are many ways in which a magnetic field can be applied, as will be apparent to those skilled in the art. The requirement for the magnetic field is that the magnetic field lines run roughly parallel to the surface 410. (In the preferred embodiment shown in FIG. 5, where the surface of the substrate is oriented in a vertical plane, the source of the magnetic field is configured so that the magnetic field lines also run vertically.) As shown in FIG. 5, the nanowires 420 are roughly aligned to the magnetic field. Furthermore, the magnetic nanowires 420 are shown to arrange themselves to form continuous lines. The arrangement of magnetic nanowires 420 shown in FIG. 5 is favored since the formation of continuous lines of magnetic nanowires is a low energy state for the magnetic circuit. Furthermore, having the substrate in a vertical orientation is expected to facilitate the movement of nanowires 420, as the nanowires 420 re-orient themselves into a lower energy state.

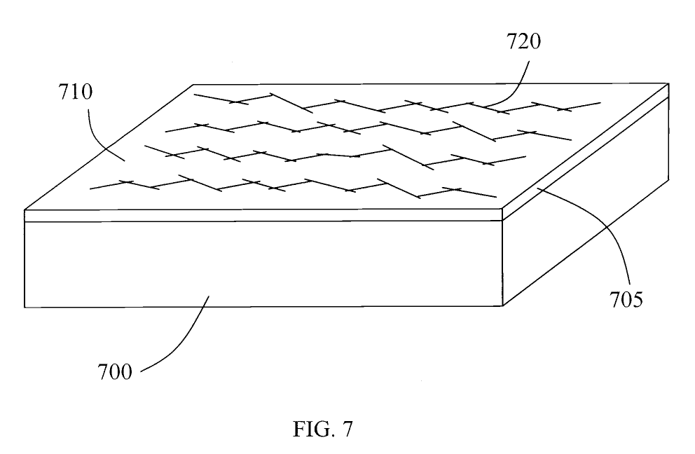

FIG. 7 illustrates a substrate 700 with a thin film 705 and oriented nanowires 720 on the film surface 710. For ease of illustration, FIG. 7 is not drawn to scale—it is intended only to illustrate the general nature of the arrangement of nanowires and the thin film on the substrate. The thin film 705 is a continuous transparent film which is substantially optically transparent and electrically conductive. The thin film 705 can be a TCO such as indium tin oxide or zinc oxide. The thin film 705 is deposited on the substrate 700 using deposition methods well known to those skilled in the art, including sputter deposition. The oriented nanowires 720 are formed into a plurality of continuous conductive pathways, as described above. Furthermore, the magnetic nanowires 720 are electrically connected to the transparent thin film 705. To help ensure good electrical contact between the nanowires 720 and the thin film 705, oxide can be removed from the nanowires prior to deposition on the thin film using an acid dip or equivalent process.

The integration of the aligned magnetic nanowires 720 and the electrically conductive, optically transparent thin film 705 provides an electrically conductive, optically transparent layer which, in preferred embodiments, has a long range electrical conductivity determined primarily by the properties of the aligned magnetic nanowires 720 and a short range electrical conductivity (on the length scale of the separation between adjacent continuous conductive pathways) determined primarily by the properties of the thin film 705. This integrated layer allows for a thin film 705 with a thickness optimized primarily for optical transparency, since the electrical conductivity is provided primarily by the aligned magnetic nanowires 720. The thin film 705 and the layer of aligned nanowires 720 are effectively two dimensional structures; therefore, the electrical conductivity of these structures can most conveniently be discussed in terms of sheet resistance. If a combination of magnetic nanowires and a thin electrically continuous conductive film is used, then it is not absolutely necessary for the magnetic nanowires to be all connected into a continuous string. Indeed, short interruptions in the string of nanowires can then be accommodated by a short current path through the electrically conductive film.

In an alternative embodiment (not shown), the aligned nanowires, as shown in FIG. 3, are coated with an electrically conductive, optically transparent layer, such as a TCO. This integrated structure is similar to the structure of FIG. 7, except the nanowires are coated by TCO rather than sitting on TCO. The TCO can be sputter deposited directly on top of the aligned nanowires and will be effective in fixing the nanowires in place in the desired configuration. The TCO can be indium tin oxide or zinc oxide. The TCO can also be deposited on the nanowire coated substrate using other deposition methods well known to those skilled in the art.

Although the present invention has been particularly described with reference to the preferred embodiments thereof, it should be readily apparent to those of ordinary skill in the art that changes and modifications in the form and details may be made without departing from the spirit and scope of the invention. For example, the methods of the present invention can be used to form conductive layers on non-planar surfaces, such as curved, or undulating surfaces. It is intended that the appended claims encompass such changes and modifications.

What is claimed is:

1. A conductive layer comprising:
a multiplicity of magnetic nanowires in a plane, said nanowires being aligned roughly (1) parallel to each other and (2) with the long axes of said nanowires in the plane of said layer, said nanowires further being configured to provide a plurality of continuous conductive pathways;
wherein the density of said multiplicity of magnetic nanowires provides substantial optical transparency of the conductive layer.

2. A conductive layer as in claim 1, wherein said magnetic nanowires comprise a transition metal.

3. A conductive layer as in claim 1, wherein said magnetic nanowires comprise a metal selected from the group consisting of nickel, cobalt and iron.

4. A conductive layer as in claim 1, wherein said magnetic nanowires are coated with a conductive metal.

5. A conductive layer as in claim 4, wherein said conductive metal is selected from the group consisting of copper, silver, gold, palladium and platinum.

6. A conductive layer as in claim 1, wherein said magnetic nanowires comprise:
a non-magnetic conductive center; and
a magnetic coating.

7. A conductive layer as in claim 1, further comprising:
a continuous conductive film, said continuous conductive film being substantially optically transparent;
wherein said multiplicity of magnetic nanowires are electrically connected to said continuous conductive film.

8. A conductive layer as in claim 7, wherein said continuous conductive film is comprised of a material selected from the group consisting of indium tin oxide and zinc oxide.

9. A conductive layer as in claim 7, wherein the electrical properties of said multiplicity of magnetic nanowires determine the sheet resistance of said conductive layer.

10. A conductive layer as in claim 7, wherein said multiplicity of magnetic nanowires are on the surface of said continuous conductive film.

11. A method of forming a conductive layer on a substrate, said conductive layer being substantially optically transparent, said method comprising:
depositing a multiplicity of magnetic conductive nanowires on said substrate; and
applying a magnetic field to form said nanowires into a plurality of conductive pathways parallel to the surface of said substrate.

12. A method as in claim 11, wherein said substrate is planar.

13. A method as in claim 12, further comprising, before said applying step, orienting the plane of the surface of said substrate vertically.

14. A method as in claim 12, wherein said magnetic field is parallel to the surface of said substrate.

15. A method is in claim 11, wherein said depositing step includes spraying a liquid suspension of said magnetic conductive nanowires onto the surface of said substrate.

16. A method is in claim 11, further comprising, after said depositing step, coating said nanowires with a conductive metal.

17. A method as in claim 16, wherein said conductive metal is selected from the group consisting of gold and silver.

18. A method as in claim 16, wherein said coating step includes electroless plating of said nanowires.

19. A method as in claim 11, wherein said coating step includes controlling the density of said multiplicity of magnetic nanowires to provide a substantially optically transparent conductive layer.

20. A method as in claim 11, further comprising, after said depositing step, coating said nanowires with a substantially optically transparent continuous conductive film.

21. A method of forming a conductive layer on a substrate, said conductive layer being substantially optically transparent, said method comprising:
depositing a continuous conductive film on said substrate, said continuous conductive film being substantially optically transparent;
depositing a multiplicity of magnetic nanowires on the surface of said continuous conductive film; and
applying a magnetic field to form said nanowires into a plurality of conductive pathways parallel to the surface of said continuous conductive film.

22. A method as in claim 21, wherein said multiplicity of magnetic nanowires are electrically connected to said continuous conductive film.
